(19) United States
(12) Patent Application Publication
(10) Pub. No.: US 2009/0201656 A1
(43) Pub. Date: Aug. 13, 2009

(54) Semiconductor package, and method of manufacturing semiconductor package

(75) Inventor: Hiroki Shibuya, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/320,050

(22) Filed: Jan. 15, 2009

(30) Foreign Application Priority Data
Feb. 8, 2008 (JP) 2008-029065

(51) Int. Cl. H05K 1/18; H01L 21/70

(52) U.S. Cl. 361/782; 438/106; 257/E21.532

(57) ABSTRACT

A semiconductor package is obtained by separately preparing a board having, as formed on the surface thereof, an interconnect pattern containing a fine pattern having a narrow interconnect pitch adapted to connection with a high-pin-count device, and a board having, as formed on the surface thereof, an interconnect pattern containing no fine pattern but only a rough pattern having a wide interconnect pitch adapted to connection with a low-pin-count device; by mounting the devices respectively on these boards; and by stacking these boards.

This application is based on Japanese patent application No. 2008-029065 the content of which is incorporated hereinto by reference.

### BACKGROUND

1. Technical Field

The present invention relates to a semiconductor package, and a method of manufacturing a semiconductor package.

2. Related Art

In recent years, semiconductor packages each containing a plurality of semiconductor chips have been developed.

FIG. 13 is a sectional view showing a configuration of a semiconductor package (stacked type) having a plurality of semiconductor chips stacked on a multilayer wiring board.

The semiconductor package 1000 contains a multilayer wiring board 1100, a semiconductor chip 1200 mounted on the multilayer wiring board 1100, a semiconductor chip 1300 stacked on the semiconductor chip 1200, and a mold resin 1220 molding the semiconductor chip 1200 and the semiconductor chip 1300. The multilayer wiring board 1100 is configured to have a resin layer 1102 and interconnects 1104 stacked therein. The semiconductor chip 1200 is connected to the multilayer wiring board 1100 through bonding wires 1210. The semiconductor chip 1300 is connected to the multilayer wiring board 1100 through bonding wires 1310. On the first surface 1110 of the multilayer wiring board 1100, on which the semiconductor chip 1200 and the semiconductor chip 1300 are placed, there is formed a fine pattern, having a narrow interconnect pitch adapted to connection with pads of the semiconductor chip 1200 and the semiconductor chip 1300. On a second surface 1112 of the multilayer wiring board 1100 to be connected to a mother board (not illustrated), there is formed a rough pattern having an interconnect pitch larger than that on the first surface 1110. The second surface 1112 of the multilayer wiring board 1100 is provided with solder balls 1002. The multilayer wiring board 1100 is connected to the mother board (not illustrated) through the solder balls 1002.

FIG. 14 is a sectional view showing a configuration of a semiconductor package (side-by-side type) having a plurality of semiconductor chips placed side-by-side on a multilayer wiring board. A semiconductor package 1004 has a configuration similar to that of the semiconductor package 1000, except that the semiconductor chip 1200 and the semiconductor chip 1300 are mounted side-by-side on the first surface 1110 side of the multilayer wiring board 1100.

There has been proposed also a chip-in-board configuration having semiconductor chips enclosed in a multilayer wiring board. The chip-in-board configuration is completed, in the process of manufacturing a multilayer wiring board, by providing a space for enclosing a semiconductor chip to the core of the board, enclosing the semiconductor chip therein, stacking an interconnect layer of the board while establishing electric connection therebetween, and stacking thereon still another semiconductor chip.

Japanese Laid-Open Patent Publication No. 2001-210954 describes a configuration having two or more electronic-component-mounting boards, having electronic components mounted thereon, stacked while placing therebetween a frame having electric passageways. The document describes that adoption of this configuration may successfully provide a multilayer board which realizes high-density mounting and excellent heat radiation performance, and allows electrical characteristic test before the package is finished.

The conventional semiconductor packages have, however, been remained unsolved in terms of improvement in yield ratio of the multilayer wiring board, and achievement of cost reduction. Some of recent semiconductor chips have a large number of pins (terminals) densely arranged thereon. Mounting of this sort of semiconductor chips raises a need of fine pattern having a narrow interconnect pitch, formed on the surface for mounting allowing thereon electrical connection with the semiconductor chips. On the other hand, for example, on the surface different from the surface on which the semiconductor chip is mounted, only a rough pattern may be good enough for the layout. The fine pattern may be even unnecessary for the purpose of mounting low-pin-count semiconductor chips, passive components and so forth. The conventional multilayer wiring boards have, however, had both of the fine pattern and the rough pattern formed in a mixed manner. A layer having the fine pattern formed therein may more readily cause failures such as short-circuiting between the adjacent interconnects. Accordingly, failures occurred in the layer having the fine pattern have resulted in overall failures of the multilayer wiring board, and have thereby resulted in degraded yield ratio and increase in the cost.

### SUMMARY

According to the present invention, there is provided a semiconductor package including:

a first device;

a first board having an interconnect pattern adapted to connection with the first device, formed on the surface thereof, and having the first device mounted on the surface thereof;

a second device; and

a second board stacked on the first board and electrically connected with the first board, having an interconnect pattern adapted to connection with the second device, formed on the surface thereof, and having the second device mounted on the surface thereof,

either one of the first device and the second device being a high-pin-count device having a large number of pins densely arranged thereon, and the other being a low-pin-count device having a fewer number of pins than the one,

wherein either one of the first board and the second board, allowing thereon mounting of the high-pin-count device, contains an interconnect pattern having a minimum interconnect pitch in the interconnect patterns formed on the first board and the second board, whereas the board allowing thereon mounting of the low-pin-count device does not contain the interconnect pattern having the minimum interconnect pitch.

Whichever of the first board and the second board herein may be provided on the upper side. The first board and the second board may be stacked directly, or stacked while placing other board(s) in between.

According to the present invention, there is also provided a method of manufacturing a semiconductor package containing a high-pin-count device having a large number of pins densely arranged thereon, and a low-pin-count device, the method includes:

separately preparing a first finished board having an interconnect pattern adapted to connection with the high-pin-count device, formed on the surface thereof, and a second finished board having, an interconnect pattern adapted to connection with the low-pin-count device, formed on the surface thereof; and mounting the high-pin-count device and the low-pin-count device respectively on the first finished board and the second finished board; and

stacking the first finished board and the second finished board,

wherein the interconnect pattern on the first finished board has a minimum interconnect pitch of the interconnect patterns formed on the first finished board and the second finished board, whereas the interconnect pattern on the second finished board does not contains the interconnect pattern having the minimum interconnect pitch.

Whichever of the first finished board and the second finished board herein may be provided on the upper side. The first finished board and the second finished board may be stacked directly, or while placing other board in between.

According to the present invention, the boards based on different design rules are separately prepared, appropriately combined and stacked, and electrically connected using electro-conductive components or the like, to thereby complete a semiconductor package. By these procedures, the semiconductor package may be obtained while ensuring a high yield ratio and low costs. More specifically, a board in need of formation of a fine pattern, causative of loss in the yield ratio, and a board only in need of a rough pattern having a small pattern density are separately prepared, and the semiconductor package is completed by combining these boards. In this way, any influence possibly exerted by the board in need of a fine pattern, which tends to cause failures, may be minimized. In addition, since the semiconductor packages may be formed by stacking the boards, after inspecting the individual boards and excluding any unacceptable ones, so that loss in the yield ratio may be reduced, and thereby the cost may be lowered. Here, “pin” means a terminal formed at one surface of a layer of a board to which bonding wires or the like are connected and may be called pad in some cases.

It is to be understood now that any arbitrary combinations of the above-described constituents, and any exchanges in the expression of the present invention among the method, device and so forth, may be effective as embodiments of the present invention.

According to the present invention, the yield ratio of the semiconductor packages may be improved, and the cost may be reduced.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view showing an exemplary configuration of the semiconductor package according to the embodiment of the present invention;

FIG. 2 is a sectional view showing an exemplary configuration of the semiconductor package according to the embodiment of the present invention;

FIG. 3 is a sectional view showing an exemplary configuration of the semiconductor package according to the embodiment of the present invention;

FIG. 4 is a sectional view showing an exemplary configuration of the semiconductor package according to the embodiment of the present invention;

FIG. 5 is a sectional view showing another exemplary configuration of the semiconductor package shown in FIG. 4;

FIG. 6 is a sectional view showing another exemplary configuration of the semiconductor package shown in FIG. 4;

FIG. 7 is a sectional view showing another exemplary configuration of the semiconductor package according to the embodiment of the present invention;

FIG. 8 is a plan view showing a configuration of the semiconductor chip;

FIG. 9 is a sectional view showing an exemplary configuration of the semiconductor package including the semiconductor chip shown in FIG. 8 according to the embodiment of the present invention;

FIG. 10 is a sectional view showing an exemplary configuration of the semiconductor package according to the embodiment of the present invention;

FIG. 11 is a sectional view showing an exemplary configuration of the semiconductor package according to the embodiment of the present invention;

FIG. 12 is a sectional view showing another exemplary configuration of the semiconductor package according to the embodiment of the present invention;

FIGS. 13 and 14 are drawings showing exemplary configurations of conventional semiconductor packages;

FIG. 15 is a plan view schematically showing a board having a fine pattern formed thereon; and

FIG. 16 is a plan view schematically showing a board having a rough pattern formed thereon.

### DETAILED DESCRIPTION

The invention will now be described herein with reference to an illustrative embodiments. Those skilled in the art will recognize that many alternative embodiments can be accomplished using the teachings of the present invention and that the invention is not limited to the embodiment illustrated for explanatory purposes.

Embodiments of the present invention will be described referring to the attached drawings. It is to be noted that any common constituents in all drawings will be given with similar reference numerals, and that the explanation will not be repeated depending on the context.

### First Embodiment

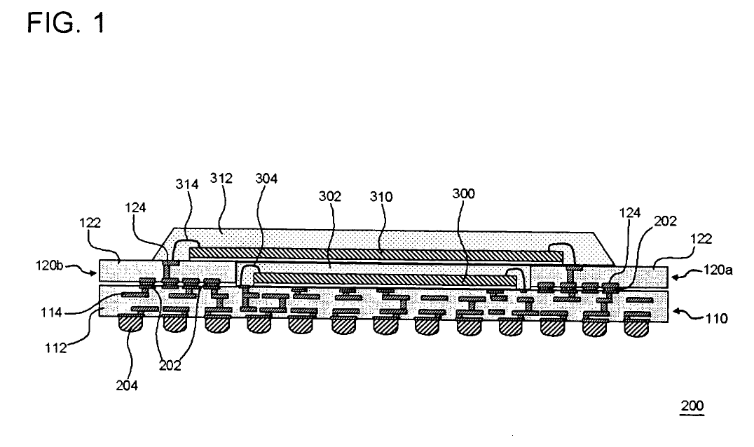

FIG. 1 is a sectional view showing an exemplary configuration of the semiconductor package according to this embodiment.

A semiconductor package 200 contains a board 110, a semiconductor chip 300 stacked on the board 110, a board 120a and a board 120b, and a semiconductor chip 310 stacked on the boards 120a and 120b. The boards 120a and 120b herein are stacked on the board 110, so as to face and surround the sides of the semiconductor chip 300. The semiconductor chip 310 is stacked on the semiconductor chip 300, and the boards 120a and 120b, so as to cover the top surface of the semiconductor chip 300. Accordingly, a configuration obtainable herein is such as having the semiconductor chip 300 enclosed by the boards 120a and 120b, and also by the semiconductor chip 310.

The board 110, and the boards 120a and 120b are multilayer wiring boards (finished boards) preliminarily finished by separate processes. The board 110 is configured by stacking a resin layer 112 and interconnect patterns 114. Similarly, the boards 120a and 120b are configured respectively by stacking a resin layer 122 and interconnect patterns 124. In this embodiment, the semiconductor chip 300 is electrically connected through bonding wires 304 to the interconnect pattern 114 on the surface of the board 110. The semiconductor chip 310 is electrically connected through bonding wires 314 respectively to the interconnect patterns 124 on the surfaces of the boards 120a and 120b. The semiconductor chip 300 and the bonding wires 304 are molded with a mold resin 302. The semiconductor chip 310 and the bonding wires 314 are molded with a mold resin 312.

The boards 110 and 120a, and the boards 110 and 120b, are electrically connected respectively through connection components 202. The connection components 202 may be configured typically by metal bumps combined with an active resin such as flux or a tape. As the connection components 202, also any anisotropic conductive materials such as an anisotropic conductive film (ACF) or anisotropic conductive paste (ACP), and film materials containing solder and any activating material such as flux, may be adoptable.

The back surface of the board 110, opposite to the top surface having the semiconductor chip 300 stacked thereon, is provided with solder balls 204. Although not illustrated herein, the board 110 is connected to a mother board through the solder balls 204.

In this embodiment, either one of the semiconductor chip 300 and the semiconductor chip 310 may be given as a high-pin-count device having a large number of pins arranged thereon, and the other one may be given as a low-pin-count device. On the surface of the board allowing thereon mounting of the high-pin-count device, there is formed a fine pattern having a narrow interconnect pitch adapted to connection with such device. The board allowing thereon mounting of the high-pin-count device may be configured so that the other surface, different from the surface having the fine pattern formed thereon, does not have the fine pattern formed thereon. On the other hand, the board allowing thereon mounting of the low-pin-count device may be configured so that none of layers contains the fine pattern, but the layers contain only a rough pattern having a wide interconnect pitch.

The fine pattern herein may be defined as including an interconnect pattern having a minimum interconnect pitch, out of all interconnect patterns formed on the board allowing thereon mounting of the high-pin-count device and the board allowing thereon mounting of the low-pin-count device. On the other hand, the rough pattern may be defined as not including an interconnect pattern having such minimum interconnect pitch.

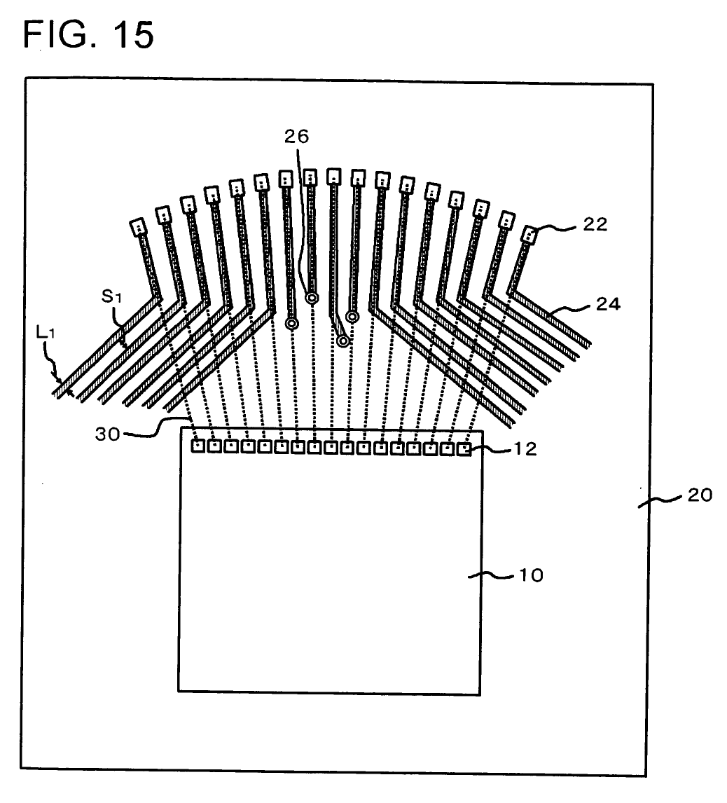

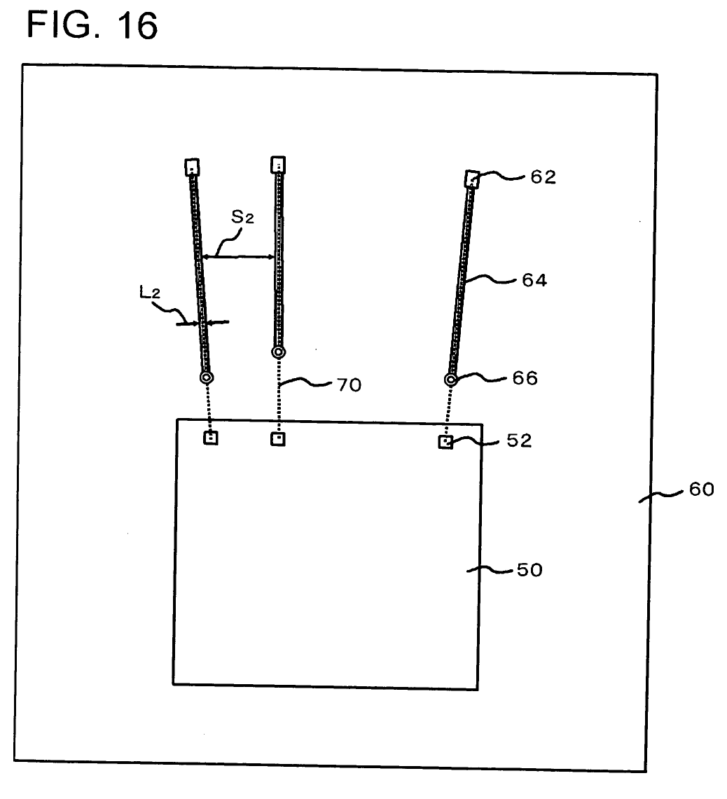

FIG. 15 is a plan view schematically showing a board 20 having a fine pattern formed thereon. FIG. 16 is a plan view schematically showing a board 60 having a rough pattern formed thereon. The pattern layouts in these drawings are shown schematically for the convenience of explanation, and are different from the actual ones. The board 20 has a device 10 having a larger number of pins 12 mounted thereon. The board 20 has a large number of terminals (stitches) 22, adapted to connection with the large number of pins (pads) 12 of the device 10 through bonding wires 30. The individual terminals 22 are connected with interconnects 24. Some of the interconnects 24 are connected to vias 26, and connected through the vias 26 to interconnects on the other surface of the board 20. Because of a need of providing such large number of terminals 22 and the interconnects 24, the interconnect pitch of the interconnect pattern on the board 20 will be dense to a considerable degree. On the other hand, the board 60 has a device 50 having a fewer number of pins 52. The board 60 has terminals (stitches) 62 provided thereon adapted to connection with the pins (pads) 52 of the device 50 through bonding wires 70. The individual terminals 62 are connected with interconnects 64. The interconnect 64 are connected to vias 66, and connected through the vias 66 to the interconnects on the other surface of the board 60. Since the number of pins 52 of the device 50 is small, it may be good enough to provide only a small number of terminals 62 and interconnects 64 on the board 60. As a consequence, the interconnect pitch of the interconnect pattern on the board 60 may be scarce, and may be configured not to contain the minimum interconnect pitch such as formed on the board 20.

In one exemplary case, the interconnects 24 on the board 20 may be configured to contain an interconnect pattern having a minimum interconnect pitch of 60 μm (line/space=30 μm/30 μm), that is, having an interconnect width L₁ of 30 μm, and a distance S₁ between the adjacent interconnects of 30 μm. On the other hand, the interconnects 64 on the board 60 may be configured to contain an interconnect pattern having a minimum interconnect pitch of 100 μm (interconnect width L₂=50 μm, distance S₂ between the adjacent interconnect=50 μm). It is to be noted that the dimensions explained in the above are only for exemplary purposes, and may appropriately be set depending on the degree of shrinkage of devices to be adopted.

Explanation will now be made referring to the case where the semiconductor chip 300 is a high-pin-count device, and the semiconductor chip 310 is a low-pin-count device. In this case, the board 110 to be connected with the semiconductor chip 300 through the bonding wires 304 is configured to have a fine pattern adapted to connection with the large number of pins of the semiconductor chip 300, and formed on the surface allowing thereon mounting of the semiconductor chip 300. On the other hand, the boards 120a and 120b, to be connected with the low-pin-count semiconductor chip 310 through the bonding wires 314, may be configured not to contain a fine pattern, but to contain only a rough pattern.

By configuring the board 110 in need of the fine pattern highly causative of failures, separately from the boards 120a and 120b in need of only the rough pattern as described in the above, influences of failures, even if unfortunately occurred, may be minimized. In addition, since these boards are stacked after being separately finished, the semiconductor packages may be formed by stacking the boards, after inspecting the individual boards and excluding any unacceptable ones. Accordingly, the yield ratio of the semiconductor packages may be improved, and the cost of the semiconductor packages may be lowered.

Next, explanation will be made referring to the case where the semiconductor chip 300 is a low-pin-count device, and the semiconductor chip 310 is a high-pin-count device. In this case, the board 110 to be connected with the semiconductor chip 300 through the bonding wires 304 may be configured not to contain a fine pattern, but to contain only a rough pattern. On the other hand, boards 120a and 120b to be connected with the high-pin-count semiconductor chip 310 through the bonding wires 314 may be configured to have a fine pattern adapted to connection with the large number of pins of the semiconductor chip 310, formed on the surface allowing thereon mounting of the semiconductor chip 310.

By configuring the boards 120a and 120b in need of the fine pattern highly causative of failures separately from the board 110 in need of only the rough pattern as described in the above, influences of failures, even if unfortunately occurred, may be minimized. In addition, since these boards are stacked after being separately finished, the semiconductor packages may be formed by stacking the boards, after inspecting the individual boards and excluding any unacceptable ones. Accordingly, the yield ratio of the semiconductor packages may be improved, and the cost of the semiconductor packages may be lowered.

Next, procedures for manufacturing the semiconductor package 200 will be explained.

First, the semiconductor chip 300 is mounted on the board 110. In this process, the semiconductor chip 300 is electrically connected through the bonding wires 304 to the interconnect pattern 114 on the surface of the board 110. Next, the semiconductor chip 300 and the bonding wires 304 are molded with the mold resin 302.

Next, the boards 120a and 120b are stacked on the board 110, so as to surround both sides of the semiconductor chip 300. The boards 110 and 120a, and the boards 110 and 110b, are then electrically connected through the connection components 202. Thereafter, the semiconductor chip 310 is stacked on the boards 120a and 120b, so as to cover the top surface of the semiconductor chip 300. The semiconductor chip 310 herein is electrically connected through the bonding wires 314 to the interconnect patterns 124 on the surfaces of the boards 120a and 120b. As a consequence, the semiconductor chip 300 is enclosed. Thereafter, the semiconductor chip 310 and the bonding wires 314 are molded with the mold resin 312.

### Second Embodiment

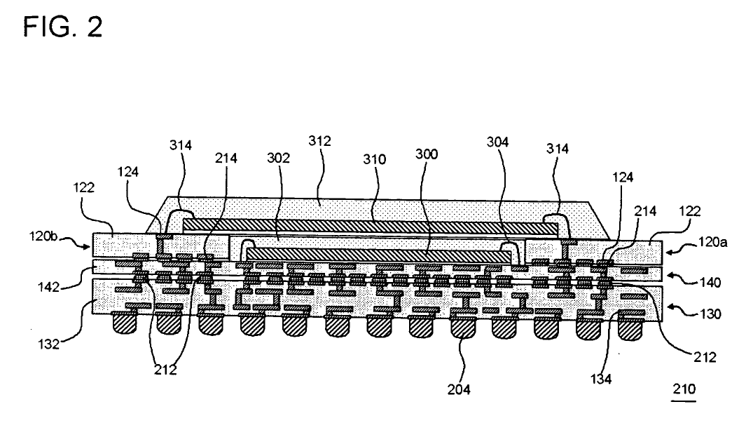

FIG. 2 is a sectional view showing an exemplary configuration of the semiconductor package according to this embodiment.

In this embodiment, a semiconductor package 210 is different from the semiconductor package 200 in that a board 130 and a board 140 are contained, in place of the board 110 of the semiconductor package 200 shown in FIG. 1. The semiconductor chip 300 herein may be configured as a high-pin-count device, and the semiconductor chip 310 may be configured as a low-pin-count device.

The board 140 is stacked on the board 130. The board 140 and the board 130 are electrically connected through connection components 212. The connection components 212 may be configured similarly to the connection components 202. In addition, the semiconductor chip 300 is mounted on the board 140. On the board 140, the board 120a and the board 120b are stacked. The board 130 is provided, on the back surface thereof, with the solder balls 204, through which the board 130 is connected to a mother board (not illustrated).

In this embodiment, the board 140 to be connected with the high-pin-count semiconductor chip 300 through the bonding wires 304 may be configured to have a fine pattern, adapted to connection with a large number of pins of the semiconductor chip 300, formed on the surface allowing thereon mounting of the semiconductor chip 300. The board 140 may be configured to have also a rough pattern formed on the back surface thereof. When the board 140 is thus configured, the board 130 may contain only the rough pattern, without containing the fine pattern. In addition, also the board 120a and the board 120b connected with the low-pin-count semiconductor chip 310 through the bonding wires 314 may be configured to contain only the rough pattern, without containing the fine pattern.

In many cases where the high-pin-count semiconductor chip 300 is mounted on a board, it may be necessary to provide the fine pattern only on the surface which is directly connected with the pins of the semiconductor chip 300, but it may be no more necessary to provide the fine pattern to the other layer(s), because the interconnects may properly be routed using vias. In this embodiment, a minimum portion in need of the fine pattern and the other portions are configured on separate boards. As a consequence, any influences of the board 140, in need of the fine pattern highly causative of failures, may be minimized.

### Third Embodiment

In this embodiment, a package-on-package (POP) configuration, having an additional semiconductor package formed on the semiconductor package 200 shown in FIG. 1, will be explained.

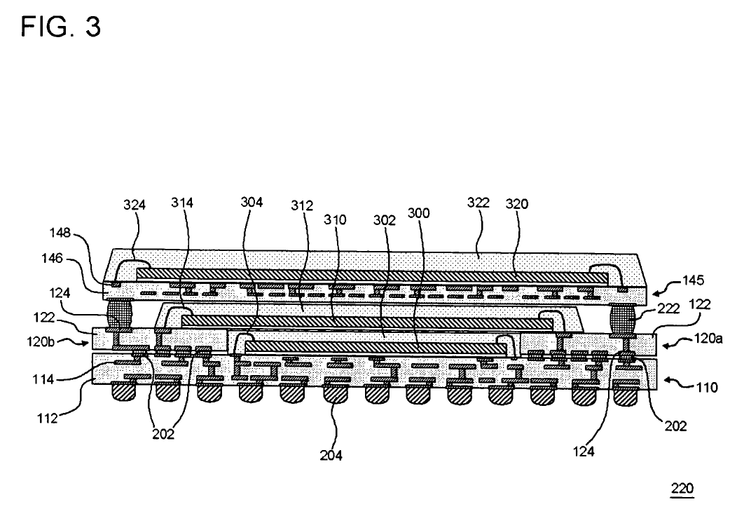

FIG. 3 is a sectional view showing an exemplary configuration of the semiconductor package of this embodiment.

A semiconductor package 220 herein is configured to have an additional semiconductor package which is composed of a board 145, a semiconductor chip 320 mounted on the board 145, and a mold resin 322 molding the semiconductor chip 320, stacked on the semiconductor package 200 shown in FIG. 1. Also the board 145 is a preliminarily finished multilayer wiring board (finished board), similarly to the boards 110, 120a and 120b. The board 145 is configured to have a resin layer 146 and interconnect patterns 148 stacked with each other. The boards 145 and 120a, and the boards 145 and 120b, are electrically connected through connection components 222. The connection components 222 may be configured similarly to the connection components 202.

Now in this embodiment, a part of the semiconductor chips 300, 310 and 320 may be given as a high-pin-count device, and the residual may be given as low-pin-count device(s). The board to be connected with the high-pin-count semiconductor chip through the bonding wires is configured to have, on the surface allowing thereon mounting of the semiconductor chip, a fine pattern adapted to connection with a large number of pins of the semiconductor chip. On the other hand, the board to be connected with the low-pin-count device through the bonding wires may be configured to contain only a rough pattern, without containing the fine pattern. As a consequence, any influences of the board 140, in need of the fine pattern highly causative of failures, may be minimized.

When the semiconductor chip 300 is the high-pin-count device, also in this embodiment, the board 110 may also be replaced with the combination of the boards 130 and 140, as explained in the second embodiment referring to FIG. 2. Alternatively, in place of the connection components 222, a board having only a rough pattern formed thereon may be provided, and the boards 145 and 120a, and the boards 145 and 120b, may electrically be connected through such board.

### Fourth Embodiment

This embodiment will show a configuration having a semiconductor chip enclosed with finished boards.

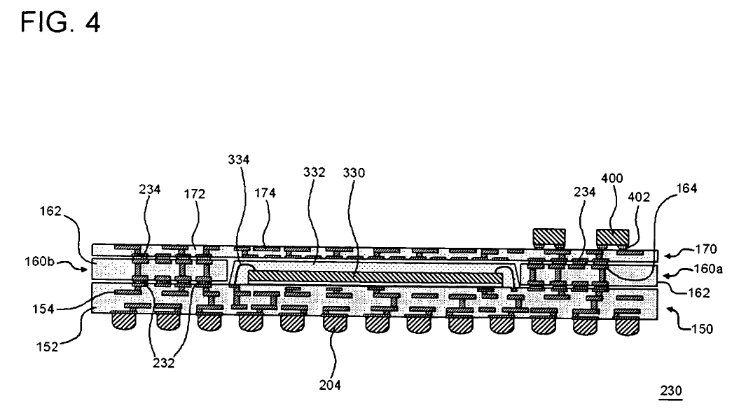

FIG. 4 is a sectional view showing an exemplary configuration of the semiconductor package of this embodiment.

A semiconductor package 230 contains a board 150, a semiconductor chip 330 stacked on the board 150, a board 160a, a board 160b, a board 170 stacked on the boards 160a and 160b, and low-pin-count devices 400 stacked on the board 170. The low-pin-count devices 400 are devices each having only a small number of pins. Each low-pin-count device 400 may be configured typically as a passive component, a filter or the like.

Each of the boards 150, 160a, 160b and 170 is a separately-and preliminarily-finished multilayer wiring board (finished board). The board 150 is configured to have a resin layer 152 and interconnect patterns 154 stacked therein. Similarly, the boards 160a and 160b are respectively configured to have a resin layer 162 and interconnect patterns 164 stacked therein. Again similarly, the board 170 is configured to have a resin layer 172 and interconnect patterns 174 stacked therein. The semiconductor chip 330 is surrounded by the boards 160a and 160b on the sides thereof, and by the board 170 on the top surface thereof, and is thereby enclosed by these boards.

The boards 150 and 160a, and the boards 150 and 160b, are electrically connected respectively through connection components 232. The boards 160a and 170, and the boards 160b and 170, are connected respectively through connection components 234. The connection components 232 and 234 may be configured similarly to the connection components 202.

The semiconductor chip 330 is electrically connected to the interconnect pattern 154 on the top surface of the board 150 through bonding wires 334. The semiconductor chip 330 and the bonding wires 334 are molded with a mold resin 332. The low-pin-count device 400 is electrically connected to the interconnect pattern 174 on the top surface of the board 170, by surface mounting with the aid of terminals 402. The board 150 is provided, on the back surface thereof, with the solder balls 204, through which the board 150 is connected to a mother board (not illustrated).

The semiconductor chip 330 herein may be given as a high-pin-count device. In this case, the board 150 to be connected with the semiconductor chip 330 through the bonding wires 334 is configured to have, on the surface allowing thereon mounting of the semiconductor chip 330, a fine pattern adapted to connection with a large number of pins of the semiconductor chip 330. On the other hand, the board 170, to be connected with the low-pin-count devices 400, and the boards 160a and 160b may be configured to contain only rough patterns, without containing the fine pattern. As a consequence, any influences of the board, in need of the fine pattern highly causative of failures, may be minimized.

Although not illustrated, the low-pin-count devices 400, which are typically filters, passive components or the like, may sometimes differ in the height from each other. In this embodiment, by enclosing the precise semiconductor chip 330 having a large number of pins inside the boards, and by arranging a plurality of low-pin-count devices 400 on the board 170, the package size may be reduced even if the low-pin-count devices 400 have different height.

Next, procedures for manufacturing the semiconductor package 230 will be explained.

First, the semiconductor chip 330 is mounted on the board 150. In this process, the semiconductor chip 330 is electrically connected through the bonding wires 334 to the interconnect pattern 154 on the board 150. Next, the semiconductor chip 330 and the bonding wires 334 are molded with the mold resin 332.

Next, the boards 160a and 160b are stacked on the board 150, so as to surround both sides of the semiconductor chip 330, and they are electrically connected through the connection components 232. Next, the board 170 is stacked on the boards 160a and 160b, so as to cover the top surface of the semiconductor chip 330, and they are electrically connected through the connection components 234. As a consequence, the semiconductor chip 330 is enclosed. Thereafter, the low-pin-count devices 400 are mounted on the board 170, and the terminals of the low-pin-count devices 400 and the interconnect pattern 174 on the surface of the board 170 are electrically connected.

As a consequence, any influences of the board, in need of the fine pattern highly causative of failures, may be minimized. In addition, the semiconductor chip 330 may be surrounded by a plurality of boards.

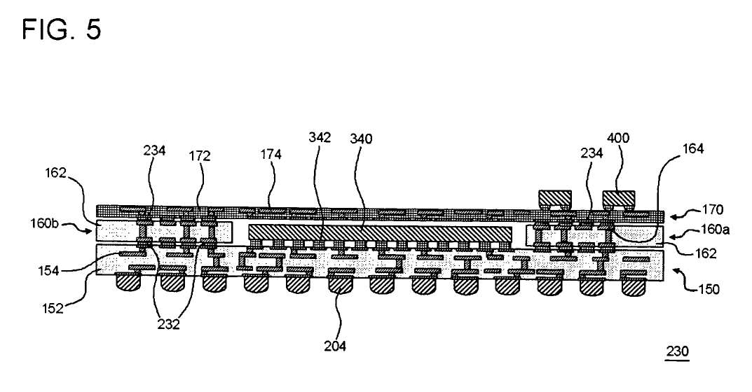

FIG. 5 is a drawing showing another example of the semiconductor package 230 shown in FIG. 4.

The semiconductor package 230 herein differs from the example shown in FIG. 4, in that it has a semiconductor chip 340 to be connected through the terminals 342 to the board 150 by flip-chip bonding. Also the semiconductor chip 340 may be given as a high-pin-count device. In this case, only the board 150 to be connected directly with the semiconductor chip 340 is necessarily provided with a fine pattern, but the other boards are not necessarily provided with the fine pattern. As a consequence, any influences of the board, in need of the fine pattern highly causative of failures, may be minimized.

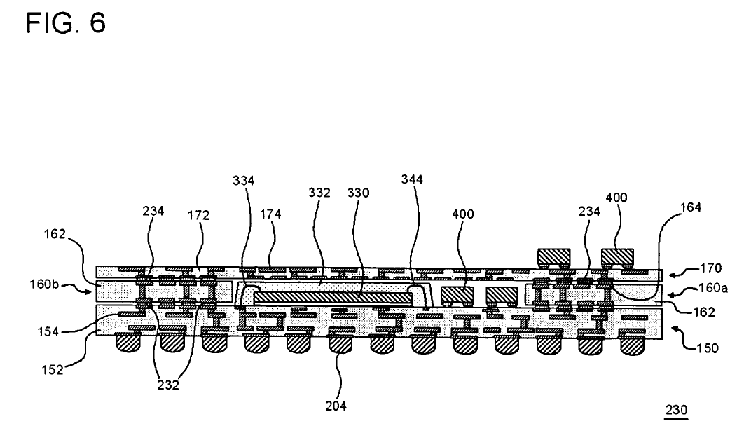

Also FIG. 6 is a drawing showing another example of the semiconductor package 230 shown in FIG. 4. On the board 150, the low-pin-count devices 400 are mounted side-by-side with the semiconductor chip 330. In this configuration, also the low-pin-count devices 400 are enclosed by a plurality of boards. Also in this configuration, the board 150 to be connected directly with the semiconductor chip 330 is necessarily provided with a fine pattern, but the other boards are not necessarily provided with the fine pattern. As a consequence, any influences of the board, in need of the fine pattern highly causative of failures, may be minimized.

When the board 150 is configured to contain the fine pattern, also in this embodiment, the board 150 may also be replaced with the combination of the boards 130 and 140, as explained in the second embodiment referring to FIG. 2.

Although the paragraphs in the above explained the exemplary case where the semiconductor chips 330 and 340, as the high-pin-count devices, are enclosed by a plurality of boards, the low-pin-count device may alternatively be enclosed by a plurality of boards.

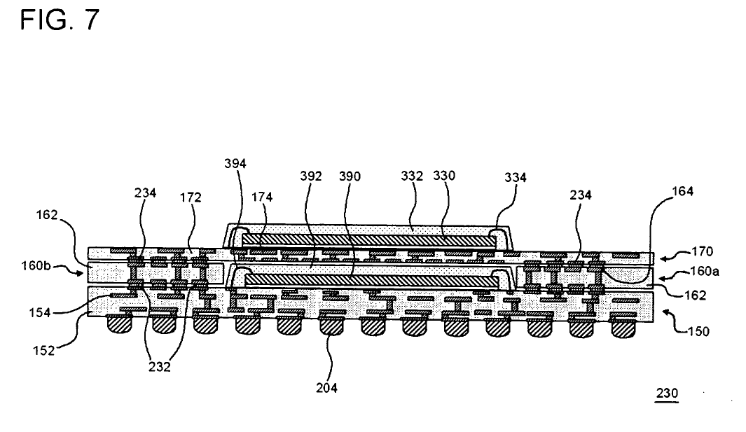

FIG. 7 is a drawing showing a configuration obtained by arranging a semiconductor chip 390, which is a low-pin-count device, on the board 150, to thereby enclose the semiconductor chip 390 by the boards 160a, 160b and 170. The semiconductor chip 390 is electrically connected through bonding wires 394 to the interconnect pattern 154 on the surface of the board 150. The semiconductor chip 390 and the bonding wires 394 are molded with a mold resin 392.

In addition, the semiconductor chip 330 as a high-pin-count device is mounted on the board 170. One possible configuration herein may be such that only the board 170 contains a fine pattern, and the boards 160a, 160b and 150 contains only rough patterns. As a consequence, any influences of the board, in need of the fine pattern highly causative of failures, may be minimized.

### Fifth Embodiment

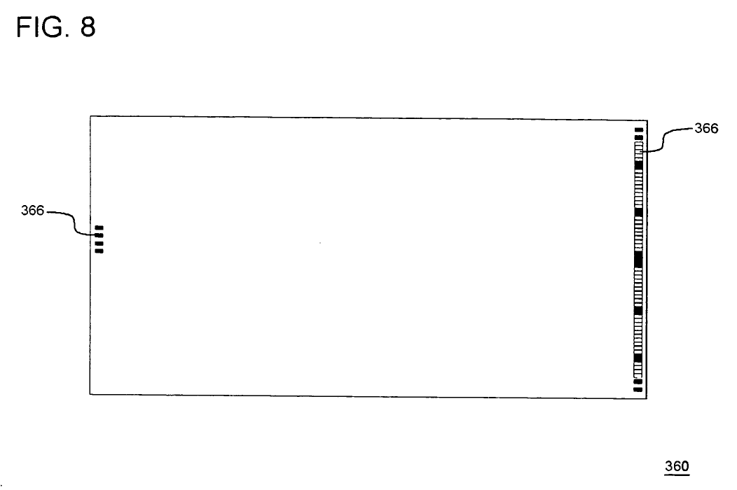

FIG. 8 is a plan view showing a configuration of a semiconductor chip 360 contained in the semiconductor package according to this embodiment. The semiconductor chip 360 has a large number of pads (pins) 366 densely arranged along one edge (on the right of the drawing), and only a few pads 366 scarcely arranged along the other edge (on the left of the drawing). For the case where thus-configured semiconductor chip 360 is mounted on a board, the board will necessarily be provided with a fine pattern, in order to allow connection with the densely-arranged pads 366 on the right of the drawing. However, the board will not necessarily be provided with the fine pattern, in order to allow connection with the scarcely-arranged pads 366 on the left of the drawing, wherein only the rough pattern will suffice. In this embodiment, a possible configuration may be such as electrically connecting one edge and the other edge of the semiconductor chip 360 respectively to different boards.

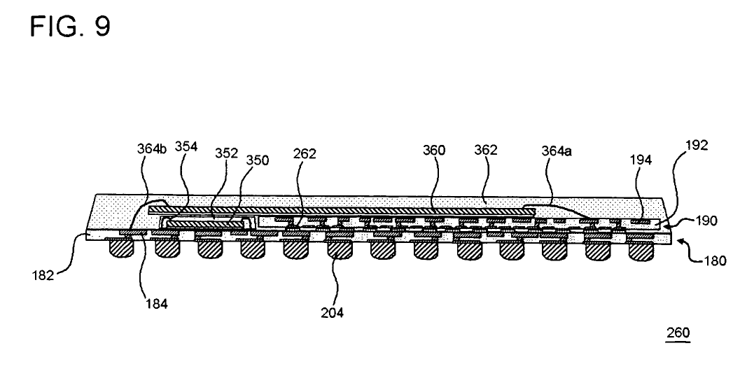

FIG. 9 is a sectional view showing an exemplary configuration of a semiconductor package 260 of this embodiment. The semiconductor package 260 contains a board 180, a semiconductor chip 350 mounted on the board 180, a board 190 stacked on the board 180, and a semiconductor chip 360 stacked on the board 190 and the semiconductor chip 350.

The boards 180 and 190 are multilayer wiring boards (finished boards) preliminarily finished by separate processes. The boards 180 and 190 are electrically connected through the connection components 262. The connection components 262 are configured similarly to the connection components 202. The board 180 is configured to contain a resin layer 182 and interconnect patterns 184 stacked therein. Similarly, the board 190 is configured to contain a resin layer 192 and interconnect patterns 194 stacked therein.

One edge side of the semiconductor chip 360 is electrically connected through bonding wires 364a to the board 190. The other edge side of the semiconductor chip 360 is electrically connected through bonding wires 364b to the board 180. The semiconductor chip 350 and the bonding wires 354 are molded with a mold resin 352. The board 190, the mold resin 352, the semiconductor chip 360, the bonding wires 364a and the bonding wires 364b are further molded with a mold resin 362.

In this configuration, a possible configuration is such that only either one of the boards 180 and 190, to be connected with the side of the semiconductor chip 360, having a large number of pads densely provided therealong, has a fine pattern, and the other contains only a rough pattern, without containing the fine pattern. Whichever board will be configured to contain the fine pattern may be determined depending on types of the semiconductor chip 350.

First, an exemplary case where the semiconductor chip 350 is a low-pin-count device will be explained. Assuming now the board 190 is configured to contain the fine pattern, the semiconductor chip 360 may be arranged so as to connect the side thereof, having a large number of pads densely provided therealong, through the bonding wires 364a to the board 190. The board 180 in this case may be configured to contain only the rough pattern, without containing the fine pattern, because it will be connected to the side of the semiconductor chip 360, having only a few pads, and will be connected to the low-pin-count semiconductor chip 350.

Next, an exemplary case where the semiconductor chip 350 is a high-pin-count device. Assuming now the board 180 is configured to contain the fine pattern, the semiconductor chip 360 may be arranged so as to connect the side thereof, having a large number of pads densely arranged therealong, through the bonding wires 364b to the board 180. The board 190 in this case may be configured to contain only the rough pattern, without containing the fine pattern, because it will be connected to the side of the semiconductor chip 360, having only a few pads.

Also in this embodiment, when the board 180 is configured to contain the fine pattern as described in the above, the board 180 may also be replaced with the combination of the boards 130 and 140, as explained in the second embodiment referring to FIG. 2.

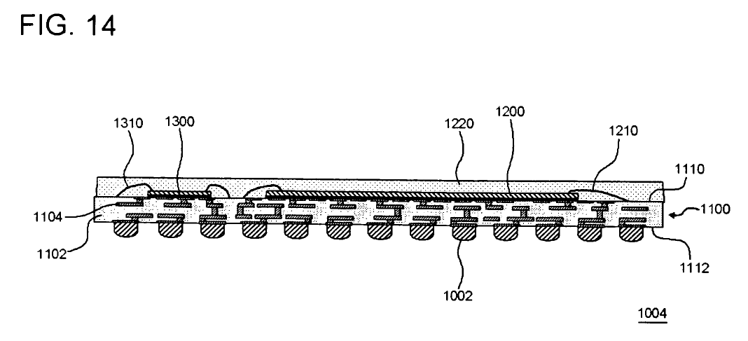

In addition, in this embodiment, a part of the semiconductor chip 360 having a larger area in a plan view, is provided so as to cover the top surface of the semiconductor chip 350 having a smaller area. Accordingly, the package size may be reduced as compared with a conventional configuration shown in FIG. 14, having a plurality of semiconductor chips arranged side-by-side on a board. Moreover, because the distance between the surface of the semiconductor chip 360 to be connected with the bonding wires 364b and the board 190 may be shortened, also the length of the bonding wires 364b may be shortened, and thereby a desirable level of easiness in assembly may be ensured.

### Sixth Embodiment

A configuration of this embodiment may be such as mounting a high-pin-count semiconductor chip and a low-pin-count semiconductor chip on the separate boards, and such as mounting the board having the high-pin-count semiconductor chip mounted thereon, on the board having the low-pin-count semiconductor chip mounted thereon.

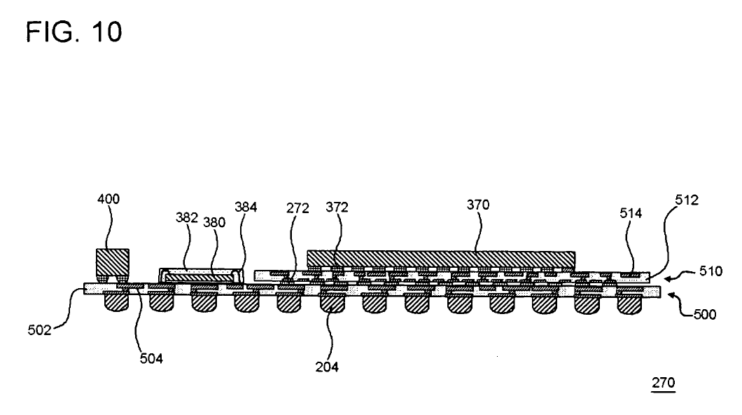

FIG. 10 is a sectional view showing an example of a semiconductor package 270 of this embodiment.

In this embodiment, the semiconductor package 270 contains a board 500; a board 510, a semiconductor chip 380 and a low-pin-count device 400 arranged side-by-side on the board 500; and a semiconductor chip 370 stacked on the board 510.

The boards 500 and 510 are multilayer wiring boards (finished boards) preliminarily finished by separate processes. The board 500 is configured to contain a resin layer 502 and interconnect patterns 504 stacked therein. Similarly, the board 510 is configured to contain a resin layer 512 and interconnect patterns 514 stacked therein.

In this embodiment, the semiconductor chip 380 is electrically connected through bonding wires 384 to an interconnect pattern 504 on the surface of the board 500. The semiconductor chip 380 and the bonding wires 384 are molded with a mold resin 382. The semiconductor chip 370 is electrically connected through terminals 372 to the interconnect pattern 514 on the surface of the board 510 by flip-chip bonding. The low-pin-count device 400 is electrically connected through terminals to the interconnect pattern 504 on the surface of the board 500.

The boards 500 and 510 are electrically connected through connection components 272. The connection components 272 may be configured similarly to the connection components 202. The back surface of the board 500, opposite to the top surface having the semiconductor chip 380 and the low-pin-count device 400 mounted thereon, is provided with the solder balls 204. Although not illustrated herein, the board 500 is connected to a mother board through the solder balls 204.

In this embodiment, the semiconductor chip 370 may be given as a high-pin-count device. The board 510 to be connected with the semiconductor chip 370 is configured to have a fine pattern adapted to connection with a large number of pins of the semiconductor chip 370, formed on the surface allowing thereon mounting of the semiconductor chip 370. On the other hand, the semiconductor chip 380 may be given as a low-pin-count device. The board 500 may be configured to contain only a rough pattern, without containing the fine pattern. As a consequence, any influences of the board, in need of the fine pattern highly causative of failures, may be minimized.

### Seventh Embodiment

A configuration of this embodiment may be such that, in the process of mounting a high-pin-count semiconductor chip onto a board, the board to be mounted with the semiconductor chip and a board to be connected to a mother board are separately provided. More specifically, a first board having a fine pattern adapted to connection with the semiconductor chip is stacked on the top surface of a second board having a rough pattern formed thereon, and a second board is provided, on the back surface thereof, with an interconnect pattern adapted to connection with a mother board.

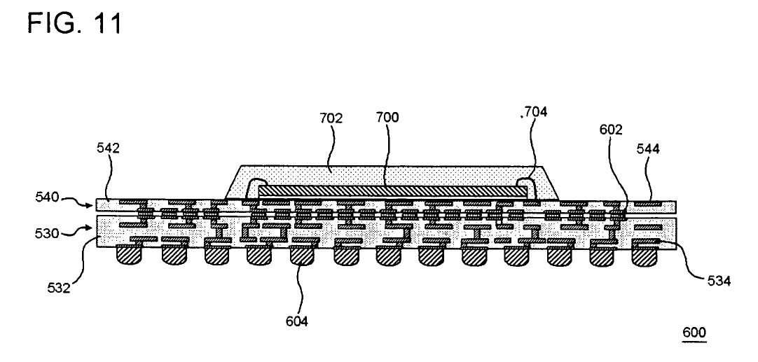

FIG. 11 is a sectional view showing an exemplary configuration of a semiconductor package 600 of this embodiment.

In this embodiment, the semiconductor package 600 contains a board 530, a board 540, and a semiconductor chip 700 mounted on the board 540. The boards 530 and 540 are multilayer wiring boards (finished boards) preliminarily finished by separate processes. The board 530 is configured to contain a resin layer 532 and interconnect patterns 534 stacked therein. The board 540 is configured to contain a resin layer 542 and interconnect patterns 544 stacked therein.

In this embodiment, the semiconductor chip 700 is electrically connected through bonding wires 704 to the interconnect pattern 544 on the surface of the board 540. The semiconductor chip 700 and the bonding wires 704 are molded with a mold resin 702. The boards 530 and 540 are electrically connected through connection components 602.

The connection components 602 may be configured typically by metal bumps combined with an activated resin or a tape. Also anisotropic conductive materials such as anisotropic conductive film (ACF) and anisotropic conductive paste (ACP), and a film material containing solder and activated material may be adoptable as the connection components 602. On the other hand, the back surface of the board 530, opposite to the top surface having the board 540 mounted thereon, is provided with solder balls 604. Although not illustrated herein, the board 530 is connected to a mother board through the solder balls 604.

In this embodiment, the semiconductor chip 700 may be given as a high-pin-count device. The board 540 to be connected with the semiconductor chip 700 is configured to have a fine pattern adapted to connection with a large number of pins of the semiconductor chip 700, formed on the surface allowing thereon mounting of the semiconductor chip 700. On the other hand, the board 530 to be connected with the mother board may be configured to contain only a rough pattern, without containing the fine pattern. By separately manufacturing the board 540 containing the fine pattern producible only with low yield ratio, and the board 530 containing only the rough pattern producible with high yield ratio as described in the above, any influences of the board, in need of the fine pattern highly causative of failures, may be minimized. As a consequence, the board of the semiconductor package 600, based on the above-described combination, may be improved in the yield ratio, and reduced in the cost.

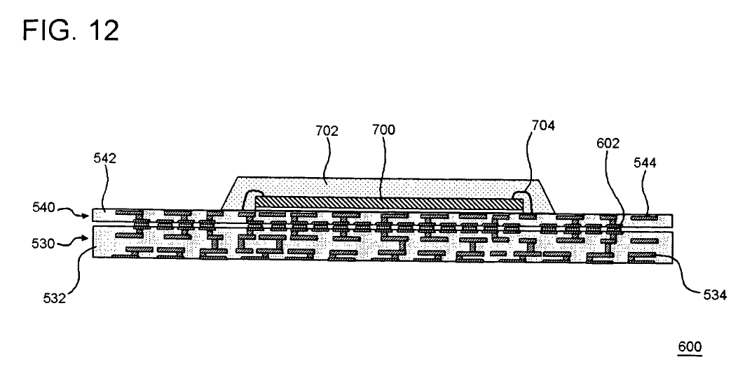

Although the description in the above showed the configuration such as connecting the board 530 through the solder balls 604 to the mother board, the board 530 may alternatively be connected, as shown in FIG. 12, to the mother board through lands in a form of LGA (land grid array).

According to the first to seventh embodiments described in the above, the effects below will be obtained.

In the first to seventh embodiments, the board in need of formation of a fine pattern causative of loss in the yield ratio may be manufactured separately from the board in need of only a rough pattern having a large interconnect pitch. As a consequence, any influences of the board, in need of the fine pattern highly causative of failures, may be minimized. In the conventional process of enclosing a semiconductor chip in the multilayer wiring boards, the interconnects were formed after the semiconductor chip was enclosed, so that any failures occurred in this process unfortunately resulted in failures of the expensive enclosed chip and all, the yield ratio of the semiconductor package degraded, and thereby the cost increased as a consequence. In contrast, according the first to seventh embodiments, the semiconductor packages may be formed by stacking the boards, after inspecting the individual boards and excluding any unacceptable ones, so that loss in the yield ratio may be reduced, and the cost may be lowered.

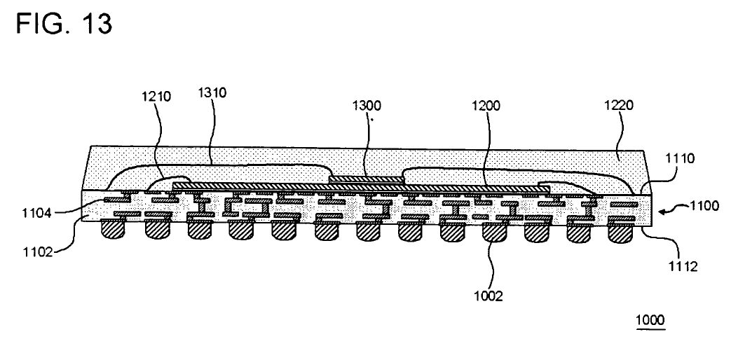

In the conventional stacked-type configuration shown in FIG. 13, mounting a smaller device by stacking it onto a larger one, easiness of assembly may be degraded due to excessively elongated wires of the smaller device. On the other hand, the side-by-side mounting of the devices as shown in FIG. 14 may enlarge the package size. In contrast, in the configurations of the first to fifth embodiments, two devices are configured so that one device is stacked on the other device, wherein each device is mounted on each board. As a consequence, the package size may be reduced, and a desired level of easiness of assembly may be ensured.

Moreover, in the conventional configuration having semiconductor chip(s), passive component(s) and so forth enclosed in the multilayer wiring boards, it was necessary to enclose the semiconductor chip(s), passive component(s) and so forth into the multilayer wiring boards, and to form the interconnect layers for establishing electrical contact with thus-enclosed semiconductor chip(s), passive component(s) and so forth. It was, therefore, necessary to manufacture the boards, configured to enclose the semiconductor chip(s), passive component(s) and so forth, in the board manufacturing line.

On the other hand, it is often difficult to confirm electrical characteristics of the semiconductor chips, passive components and so forth by board manufactures (in the board manufacturing lines). For the case of enclosing the semiconductor chip(s), passive component(s) and so forth, it was conventionally necessary for the manufacturers of semiconductor chips, passive components and so forth, for example, to provide the board manufacturers with a KGD (known good die), which guarantees quality of these components in a form of wafer or die obtained by dicing, in order to prevent the semiconductor chip(s), passive component(s) and so forth causing operation failures, from being enclosed in the boards. Solution using a KGD, however, raises not only a need of electrical characteristics inspection (screening), which has conventionally been executed in the state of wafer, but also a need or executing the electrical characteristics inspection (screening), which is usually executed only in the state of final semiconductor package, also in the state of wafer, and for some sort of product, may still also raise a need of executing electrical characteristics test (screening) at high and low temperatures, or BT (burn-in test) in the state of wafer. For these reasons, the KGB solution is difficult as compared with the quality assurance by executing electrical characteristics test (screening) in the form of final semiconductor package. In addition, even if the semiconductor chips, passive components and so forth were provided as the KGDs, the semiconductor chips, passive components and so forth may cause operation failures due to stress ascribable to enclosing operation (embedding) in the boards. Accordingly, if the board manufacturers were incapable of executing the electrical characteristics test of the enclosed components (semiconductor chips, passive components and so forth) as described in the above, they were suffering from difficulty in assurance of operations and quality of the enclosed components (semiconductor chips, passive components and so forth) after being enclosed (embedded) in the boards. Even if the board manufacturers should be capable of executing electrical characteristics test of the enclosed components (semiconductor chips, passive components and so forth), the chip manufacturers are then requested to disclose results of inspection of the semiconductor chips and so forth, including know-how, to the board manufacturers, so that some countermeasures for leakage of secrets were necessary. As described in the above, enclosing operation of the semiconductor chips was difficult to be dealt with, only by either one of the board manufacturing line and the package assembly line, and was suffering from a problem of more complicated manufacturing processes and larger costs.

On the contrary, in the first to fifth embodiments, the semiconductor chips, passive components and so forth are configured based on combination (connection) with the preliminarily finished boards. Accordingly, the final semiconductor chips, having desired semiconductor chips enclosed therein and mounted thereon, may be manufactured only by the package assembly line. In other words, it may be no more necessary to hand over the semiconductor chips to the board manufacturing line. In the package assembly line, the semiconductor devices may be manufactured by receiving desired boards from the board manufacturing line, and then packaging them. For example, it may therefore be possible for a manufacturer capable of both of manufacturing of semiconductor chips and package assembly, to manufacture the semiconductor devices solely within the company, so that the manufacturing processes may be simplified, and the cost may be reduced. Since only the package assembly line may be good enough to manufacture the semiconductor packages enclosing the semiconductor chips, problems of quality assurance and countermeasures for leakage of secrets may be solved.

There was another problem in the prior art such that, in order to enclose the semiconductor chip(s) in the core of the boards, and to establish electrical contact between the interconnects on the boards and the pads of the semiconductor chip(s), the pads on the semiconductor chips were necessarily arrayed, and therefore the semiconductor chips were necessarily application-specific to some degree. It was, therefore, difficult to adopt the prior art to the semiconductor chips having peripheral pads, manufactured on the premise that they are electrically connected with bonding wires. In contrast in the first to fifth embodiments, since the preliminarily finished boards are combined in the package assembly process, the semiconductor chip(s) may be enclosed only by existing assembly techniques, such as wire bonding, flip-chip bonding and so forth, irrespective of types and geometries of the semiconductor chip(s) to be enclosed. Still another configuration allowable herein may be based on integrated mounting with appropriate passive components or the like.

The embodiments of the present invention have been described in the above referring to the attached drawings, merely as examples of the present invention, wherein various configurations other than those described in the above may be adoptable.

The embodiments described in the above showed the configurations having the semiconductor chip(s) enclosed by the boards and other semiconductor chip. In these cases, the semiconductor chip(s) to be enclosed may be surrounded along all of four sides, or may be surrounded while being partially opened rather than being surrounded along all of four sides. By adopting such partially-opened configuration so as to make the enclosed semiconductor chip(s) engaged with the outer space, heat generated by the semiconductor chip(s) may efficiently be radiated outside the boards. The configuration may be advantageous also in that the finished semiconductor package may be kept readily cleanable, if the semiconductor chip(s) need be cleaned. Of course, the semiconductor chip(s) may tightly be enclosed by providing the boards along all of four sides so as to improve the reliability, so far as the configuration is unsusceptible to the problem of heat generation, or unnecessarily be cleaned.

In addition, the boards including the boards 120a, 120b, 160a, 160b and so forth, arranged on the sides of the semiconductor chip(s), may be given in an integrated manner, so far as they are preliminarily configured to give a space allowing therein arrangement of the semiconductor chip(s).

The above-described embodiments respectively showed the configurations having the semiconductor chip(s) bonded through the bonding wires to the board(s), and configurations having the semiconductor chip(s) connected through the terminals by flip-chip bonding. Whichever method of bonding will be adopted to which embodiment may appropriately be selectable. According to the present invention, the process may appropriately and freely be designable, depending on types of the semiconductor chips.

It is apparent that the present invention is not limited to the above embodiment, that may be modified and changed without departing from the scope and spirit of the invention.

What is claimed is:

1. A semiconductor package comprising:
a first device;
a first board having an interconnect pattern adapted to connection with said first device, formed on the surface thereof, and having said first device mounted on said surface thereof;
a second device; and
a second board stacked on said first board and electrically connected with said first board, having an interconnect pattern adapted to connection with said second device, formed on the surface thereof, and having said second device mounted on said surface thereof,
either one of said first device and said second device being a high-pin-count device having a large number of pins densely arranged thereon, and the other being a low-pin-count device having a fewer number of pins than said one,
wherein either one of said first board and said second board, allowing thereon mounting of said high-pin-count device, contains an interconnect pattern having a minimum interconnect pitch in the interconnect patterns formed on said first board and said second board, whereas the board allowing thereon mounting of said low-pin-count device does not contain said interconnect pattern having said minimum interconnect pitch.

2. The semiconductor package as claimed in claim 1, further comprising:
a third board having no interconnect pattern having the minimum interconnect pitch, but having connection points with a mother board, formed on the back surface thereof,
wherein said first device is said high-pin-count device, and
said first board is stacked over said third board, and is electrically connected with said third board.

3. The semiconductor package as claimed in claim 1, further comprising:
a fourth board containing no interconnect pattern having said minimum interconnect pitch,
wherein said first device and said fourth board are stacked side-by-side on the surface of said first board, so that said fourth board surrounds the sides of said first device, and said fourth board and said first board are electrically connected, and
said second board is stacked over the surfaces of said first device and said fourth board so as to cover the top surface of the said first device, and is electrically connected with said fourth board.

4. The semiconductor package as claimed in claim 1,
wherein said first device and said second board are stacked side-by-side on the surface of said first board, so that said second board surrounds the sides of said first device.

5. The semiconductor package as claimed in claim 1,
wherein said first device is said low-pin-count device,
said second device is said high-pin-count device, having a large number of pins densely arranged on one edge side, while having a low-pin-count structure on the other edge side,
said first device and said second board are stacked side-by-side on the surface said first board, and
said second device is connected to said second board on said one edge side, and connected to said first board on said other edge side.

6. The semiconductor package as claimed in claim 4,
wherein said second device is stacked on the surfaces of said first device and said second board, so as to cover the top surface of said first device.

7. The semiconductor package as claimed in claim 5,
wherein said second device is stacked on the surfaces of said first device and said second board, so as to cover the top surface of said first device.

8. The semiconductor package as claimed in claim 1,
wherein said first device is said low-pin-count device,
said second device is said high-pin-count device, and
said first device and said second board are stacked side-by-side on the surface of said first board.

9. The semiconductor package as claimed in claim 8,
wherein said first board has, as provided on the back surface thereof, connection points adapted to connection with a mother board.

10. The semiconductor package as claimed in claim 1,
wherein said high-pin-count device is a semiconductor chip, and said low-pin-count device is a passive component or a filter.

11. The semiconductor package as claimed in claim 1,
wherein said boards stacked with each other are electrically connected via electro-conductive components.

12. A method of manufacturing a semiconductor package containing a high-pin-count device having a large number of pins densely arranged thereon, and a low-pin-count device, said method comprising:
separately preparing a first finished board having an interconnect pattern adapted to connection with said high-pin-count device, formed on the surface thereof, and a second finished board having an interconnect pattern adapted to connection with said low-pin-count device, formed on the surface thereof; and mounting said high-pin-count device and said low-pin-count device respectively on said first finished board and said second finished board; and
stacking said first finished board and said second finished board,
wherein said interconnect pattern on said first finished board has a minimum interconnect pitch of the interconnect patterns formed on said first finished board and said second finished board, whereas the interconnect pattern on the second finished board does not contain any interconnect pattern having the minimum interconnect pitch.

13. The method of manufacturing a semiconductor package as claimed in claim 12,
wherein in said stacking said first finished board and said second finished board, said first finished board and said second finished board are stacked, so that said high-pin-count device is enclosed by said low-pin-count device, said first finished board, said second finished board, or any other finished board containing no interconnect pattern having said minimum interconnect pitch.
